(19) United States
(12) Patent Application Publication
(10) Pub. No.: US 2026/0052986 A1
(43) Pub. Date: Feb. 19, 2026

(54) DIAMOND-BASED INTEGRATED CIRCUIT PACKAGE LID

(71) Applicant: NVIDIA Corporation, Santa Clara, CA (US)

(72) Inventors: Padam Jain, San Jose, CA (US); Shantanu Kalchuri, San Jose, CA (US); Mohammed Godil, Vancouver, WA (US)

(21) Appl. No.: 18/807,721

(22) Filed: Aug. 16, 2024

(51) Int. Cl. H01L 23/373; H01L 23/00; H01L 23/04; H01L 23/367; H01L 23/46; H01L 25/00

(52) U.S. Cl. CPC H01L 23/3732; H01L 23/04; H01L 23/3677; H01L 23/46; H01L 24/32; H01L 25/00; H01L 2224/32225

(57) ABSTRACT

Many electronic devices generate significant amounts of heat during operation, especially those configured for high-performance computing often used to support machine learning/artificial intelligence (ML/AI) applications. However, operating electronic devices at increased temperatures can negatively impact their performance. While it is now common for integrated circuit packages to include a lid that can be coupled to a cooling plate providing heat dissipation, the lid is currently fabricated from copper metal which limits thermal conductivity and thus the ability to provide heat dissipation for the underlying integrated circuit. The present disclosure provide a diamond-based lid for an integrated circuit package, which can provide higher thermal conductivity than the existing copper lids.

### TECHNICAL FIELD

The present disclosure relates to integrated circuit packages.

### BACKGROUND

Many electronic devices generate significant amounts of heat during operation, especially those configured for high-performance computing often used to support machine learning/artificial intelligence (ML/AI) applications. Generally, a higher power capability will translate into higher performance for these devices, but at the cost of increased heat generation. However, operating electronic devices at increased temperatures can negatively impact their performance, and furthermore when an electronic device gets overheated some of its components with lower thermal ratings can be damaged. There has thus been a focus on heat dissipation for electronic devices.

To address the heat generated by semiconductor dies, there are several existing solutions that focus on decreasing the thermal resistance of the heat path between the silicon and heat sink. For example, these solutions have included air cooling and even more recently liquid cooling in the form of cold plates, but the presence of polymer-based thermal interface material (TIM) between the semiconductor die and the cold plate is a limiter in maximizing the benefit of the cold plate.

It is also now common for the integrated circuit packaging to include a lid to help avoid package warpage, where the lid is fabricated from copper metal and may be configured to have inbuilt microchannels for fluid flow. Unfortunately, currently used fabrication process is a skiving process which allows for only a uniform fluid channel structure in the lid. In addition, the current use of copper metal limits thermal conductivity to 400 watts per meter-kelvin (W/m-K).

There is a need for addressing these issues and/or other issues associated with the prior art. For example, there is a need to provide a diamond-based lid for an integrated circuit package, which can provide higher thermal conductivity than existing copper lids and which can allow for non-uniform channels.

### SUMMARY

In an embodiment, a diamond-based lid for an integrated circuit package is provided. The lid includes a base layer comprised of a diamond-based material. The lid further includes at least one structure coupled to a top surface of the base layer, wherein the at least one structure is configured for providing heat dissipation.

### BRIEF DESCRIPTION OF THE DRAWINGS

FIG. 1 illustrates a diamond-based lid for an integrated circuit package, in accordance with an embodiment.

FIG. 2 illustrates an integrated circuit package having a diamond-based lid with a heat dissipation structure, in accordance with an embodiment.

FIG. 3 illustrates an integrated circuit package having a diamond-based lid fabricated with support structures, in accordance with an embodiment.

FIG. 4 illustrates an integrated circuit package having a flat diamond-based lid coupled to molded support structures, in accordance with an embodiment.

FIG. 5 illustrates an integrated circuit package having a diamond-based lid forming a base of a cold plate, in accordance with an embodiment.

FIG. 6 illustrates an integrated circuit package having a flat diamond-based lid coupled to independently fabricated support structures, in accordance with an embodiment.

FIG. 7 illustrates an exemplary computing system, in accordance with an embodiment.

### DETAILED DESCRIPTION

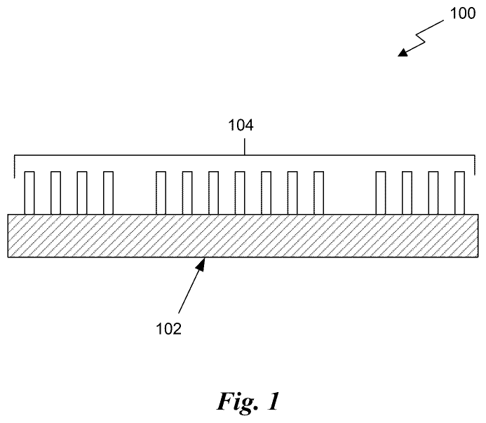

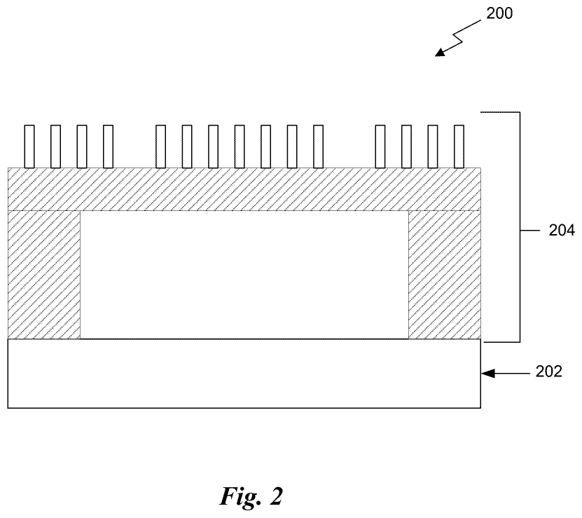

FIG. 1 illustrates a diamond-based lid 100 for an integrated circuit package, in accordance with an embodiment. In the context of the present description, the lid 100 refers to a top covering fabricated for an integrated circuit package. In the context of the present description, an integrated circuit package refers to structure fabricated to at least partially house at least one integrated circuit (e.g. die). In an embodiment, the lid 100 may be a component of the integrated circuit package. In an embodiment, the lid 100 may be fabricated separately from other components of the integrated circuit package. Various examples of the integrated circuit package having the diamond-based lid 100 are described below with reference to FIGS. 2-6.

As shown, the lid 100 includes a base layer 102 that is comprised of a diamond-based material. In an embodiment, the diamond-based material may be a diamond sheet. In an embodiment, the diamond-based material may be a diamond-based composite material. The diamond-based composite material may be silver-diamond composite material, a copper-diamond composite material, or another composite material that is made up of a combination of diamond and at least one other material (e.g. metal).

By virtue of the lid 100 being comprised of a diamond-based material, a thermal conductivity of the lid may be greater than a lid fabricated from other diamond-less materials, such as copper. In an embodiment, the diamond-based material may have a thermal conductivity greater than 400 watts per meter-kelvin (W/m-K). In an embodiment, the diamond-based material may have a thermal conductivity greater than 800 W/m-K.

In an embodiment, at least a portion of a bottom surface (underside) of the base layer 102 of the lid 100 may be flat. In an embodiment, at least a portion of a top surface (topside) of the base layer 102 of the lid may be flat. In an embodiment, at least a portion of the base layer 102 of the lid 100 may be solid (i.e. without gaps, openings, etc.).

As further shown, the lid 100 includes at least one structure 104 coupled to the top surface of the base layer 102 of the lid. In the context of the present embodiment, the at least one structure 104 is configured for providing heat dissipation. In an embodiment, the at least one structure 104 may allow for liquid to flow therethrough to provide heat dissipation (i.e. dissipation of heat generated by an integrated circuit covered by the lid 100 and thus cooling of the integrated circuit). In an embodiment, the lid 100 as described herein may be considered a cold plate that provides the heat dissipation.

In an embodiment, the at least one structure 104 may be at least one channel, such as a copper plated channel. The channel may be rectangular, in an embodiment. In an embodiment, the at least one channel may be a plurality of uniform channels. In an embodiment, the at least one channel may be a plurality of non-uniform channels. Just by way of example, using an additive plating process, at least one channel (e.g. microchannel) can be plated with copper on top of the diamond-based material of the base layer 102 of the lid 100. The additive plating process may allow for the non-uniform channel structure which can be optimized for both non-uniform thermal map and pressure drop. In an embodiment, at least one channel may be plated directly on top of the diamond-based material of the base layer 102 of the lid 100 or on top of a seed layer deposited on the diamond-based material of the base layer 102 of the lid 100.

In an embodiment, the at least one structure 104 may be at least one a pin array structure. In an embodiment, the pin array structure may be uniform. In an embodiment, the pin array structure may be non-uniform. In an embodiment, the pin array structure may be coupled to the top surface of the base layer 102 of the lid 100 via a film deposited on the top surface of the base layer 102 of the lid 100. In an embodiment, the film may be a nickel-gold composite material or a nickel-silver composite material. For example, the diamond-based material used for the base layer 102 of the lid 100 can be made solderable by depositing a nickel-gold composite film or a nickel-silver composite or some other composite film that will allow the lid 100 to have the pin array structure.

The at least one structure 104 may be configured to provide multiple independent cooling loops which in turn can provide for targeted cooling of any integrated circuit(s) covered by the lid 100. The at least one structure 104 may be configured to cool large dies by having multiple smaller modular cooling structures to circumvent die curvature and thermal stress related issues.

More illustrative information will now be set forth regarding various optional architectures and features with which the foregoing framework may be implemented, per the desires of the user. It should be strongly noted that the following information is set forth for illustrative purposes and should not be construed as limiting in any manner. Any of the following features may be optionally incorporated with or without the exclusion of other features described.

FIG. 2 illustrates an integrated circuit package 200 having a diamond-based lid with a heat dissipation structure, in accordance with an embodiment. The diamond-based lid of the present integrated circuit package 200 may be structured in accordance with the diamond-based lid 100 of FIG. 1. The definitions and descriptions given above may equally apply to the present embodiment.

As shown, the integrated circuit package 200 includes a base substrate 202. The base substrate 202 is a structure to which an integrated circuit may be coupled, either directly or indirectly. In an embodiment, the base substrate 202 may be configured to have at least one die coupled thereto. In an embodiment, The base substrate 202 may include a dielectric material (e.g. a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the top and bottom surfaces of the base substrate 202, or between different locations on the top surface, and/or between different locations on the bottom surface.

The integrated circuit package 200 also includes a lid 204 having a base layer comprised of a diamond-based material and having at least one structure coupled to a top surface of the base layer of the lid 204 which is configured to provide heat dissipation. As shown, the lid 204 is coupled to the base substrate 202 via at least one support structure. The base layer of the lid 204 is configured to provide a top cover to any integrated circuit that is coupled to the base substrate 202. The support structure is configured to provide an outer cover to the integrated circuit that is coupled to the base substrate 202. In an embodiment, the support structure may be structured as a frame coupled to a periphery of a top surface of the base substrate 202 such that the support structure surrounds the integrated circuit that is coupled to the base substrate 202.

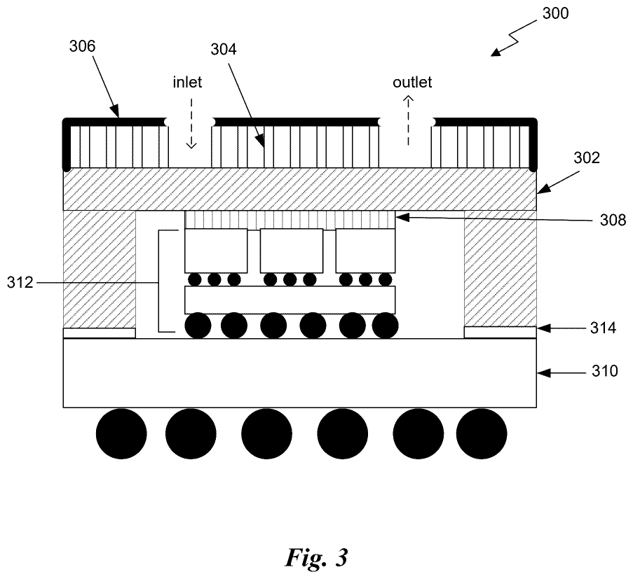

In an embodiment, the support structure may be coupled to the base layer of the lid 204 and may be configured to couple the lid 204 to the base substrate 202 of the integrated circuit package 200. In an embodiment, the support structure and the base layer of the lid 204 may be fabricated together (i.e. of the same diamond-based material). In another embodiment, the support structure may be fabricated separately from the base layer of the lid 204 and may be coupled to the base layer of the lid 204 (e.g. via a polymer-based adhesive). In this embodiment, the support structure may be comprised of the same diamond-based material as the base layer of the lid 204 or may be comprised of another material, such as a copper, stainless steel, etc. Various exemplary embodiments of the support structure(s) via which the base substrate 202 and the lid 204 are coupled will be described with reference to FIGS. 3-6 below.

FIG. 3 illustrates an integrated circuit package 300 having a diamond-based lid fabricated with support structures, in accordance with an embodiment. The integrated circuit package 300 illustrates one possible implementation of the integrated circuit package 200 of FIG. 2. Accordingly, the definitions and descriptions given above may equally apply to the present embodiment.

As shown, the integrated circuit package 300 includes a base substrate 310 to which an integrated circuit 312 is coupled. While only one integrated circuit 312 is shown, it should be noted that multiple of such integrated circuits may be coupled to the base substrate 310. Accordingly, any reference to the integrated circuit 312 can equally be applied to multiple of such integrated circuits.

The integrated circuit package 300 also includes a lid having a base layer 302 comprised of a diamond-based material and having at least one structure 304 coupled to a top surface of the base layer 302 which is configured to provide heat dissipation. The base layer 302 is fabricated with support structures that couple the base layer 302 of the lid to the base substrate 310. The support structures extend downward from a periphery of a bottom surface of the base layer 302 of the lid to frame, or surround, the integrated circuit 312. In the embodiment shown, the support structures of the base layer 302 of the lid couple to the base substrate 310 via an adhesive 314, such as a polymer-based adhesive.

In the present embodiment shown, a TIM 308 is situated between the integrated circuit 312 and the base layer 302 of the lid. In an embodiment, the TIM 308 may be directly or indirectly coupled to a top surface of the integrated circuit 312. In an embodiment, the TIM 308 may be directly or indirectly coupled to a bottom surface of the base layer 302 of the lid. The TIM 308 may be a polymer-based material, a film-based material, a metal-based material, etc.

Also in the present embodiment shown, the lid includes a top cover 306 that at least partially encloses the at least one heat dissipation structure 304. The top cover 306 may be comprised of a copper-based material, an aluminum-based material, a plastic-based material, etc. The top cover 306 includes support structures that directly or indirectly couple to the base layer 302. As shown, the top cover 306 includes openings configured as at least one inlet and at least one outlet (e.g. via which the liquid can flow into and out of the heat dissipation structure 304. It should be noted that more generally the top cover 306 may include at least one opening configured as at least one of an inlet or an outlet to the at least one heat dissipation structure 304.

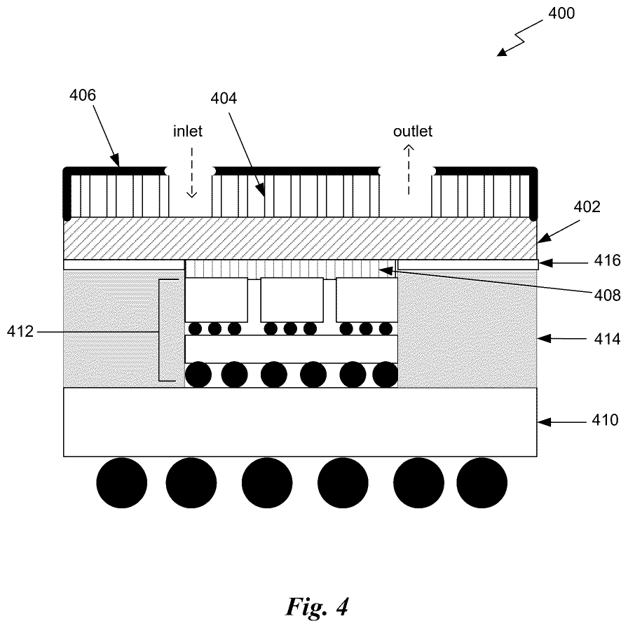

FIG. 4 illustrates an integrated circuit package 400 having a flat diamond-based lid coupled to molded support structures, in accordance with an embodiment. The integrated circuit package 400 illustrates one possible implementation of the integrated circuit package 200 of FIG. 2. Accordingly, the definitions and descriptions given above may equally apply to the present embodiment.

As shown, the integrated circuit package 400 includes a base substrate 410 to which an integrated circuit 412 is coupled. The integrated circuit package 400 also includes a lid having a base layer 402 comprised of a diamond-based material and having at least one structure 404 coupled to a top surface of the base layer 402 which is configured to provide heat dissipation. Unlike the integrated circuit package 300 of FIG. 3, the base layer 402 of the present embodiment is fabricated without a support structure to couple the base layer 402 of the lid to the base substrate 410. Instead, in the present embodiment, at least one support structure 414 is fabricated separately from the base layer 402 of the lid, but nevertheless couples the base layer 402 of the lid to the base substrate 410 at a periphery of the bottom and top surfaces respectively. In an embodiment, the support structure 414 may be comprised of a mold material that directly couples to the base substrate 410. In an embodiment, the support structure 414 may be coupled to the base layer 402 of the lid via an adhesive 416.

In the present embodiment shown, a TIM 408 is situated between the integrated circuit 412 and the base layer 402 of the lid. The TIM 408 is the same as that described above with respect to the integrated circuit package 300 of FIG. 3. Also in the present embodiment shown, the lid includes a top cover 406 that at least partially encloses the at least one heat dissipation structure 404. The top cover 406 is the same as that described above with respect to the integrated circuit package 300 of FIG. 3.

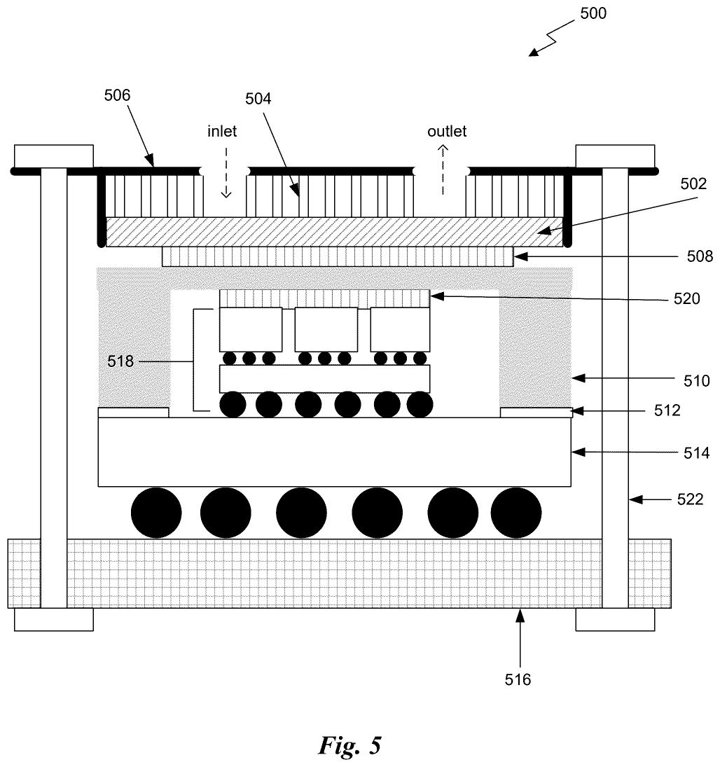

FIG. 5 illustrates an integrated circuit package 500 having a diamond-based lid forming a base of a cold plate, in accordance with an embodiment. The integrated circuit package 500 illustrates one possible implementation of the integrated circuit package 200 of FIG. 2. Accordingly, the definitions and descriptions given above may equally apply to the present embodiment.

As shown, the integrated circuit package 500 includes a base substrate 514 to which an integrated circuit 518 is coupled. The integrated circuit package 500 also includes a lid having a base layer 502 comprised of a diamond-based material and having at least one structure 504 coupled to a top surface of the base layer 502 which is configured to provide heat dissipation.

Unlike the integrated circuit package 300 of FIG. 3 and the integrated circuit package 400 of FIG. 4, the support structure 510 coupling the base substrate 514 to the base layer 502 of the lid includes both (1) a portion framing an outside of the integrated circuit 518 and (2) a top layer covering a top surface of the integrated circuit 518. A TIM 520 is situated between the integrated circuit 518 and the top layer of the support structure 510. The framing portion of the support structure 510 couples to the base substrate 514 via an adhesive 512, for example. The top layer of the support structure 510 indirectly couples to a bottom surface of the base layer 502 of the lid via a secondary TIM 508.

Also in the present embodiment shown, the lid includes a top cover 506 that at least partially encloses the at least one heat dissipation structure 504. The top cover 506 is the same as that described above with respect to the integrated circuit package 300 of FIG. 3.

Further, the integrated circuit package 500 includes a loading mechanism 522 coupled to the top cover 506 of the lid and a printed circuit board (PCB) 516 at a base of the integrated circuit package 500. The loading mechanism 522 clamps the lid onto the remaining portion of the integrated circuit package 500. The loading mechanism 522 may include a plurality of spring loaded screws, for example.

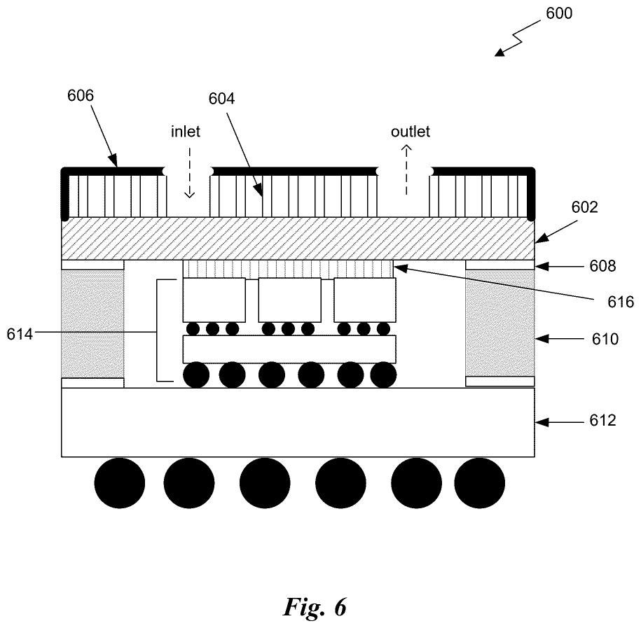

FIG. 6 illustrates an integrated circuit package 600 having a flat diamond-based lid coupled to independently fabricated support structures, in accordance with an embodiment. The integrated circuit package 600 illustrates one possible implementation of the integrated circuit package 200 of FIG. 2. Accordingly, the definitions and descriptions given above may equally apply to the present embodiment.

As shown, the integrated circuit package 600 includes a base substrate 612 to which an integrated circuit 614 is coupled. The integrated circuit package 600 also includes a lid having a base layer 602 comprised of a diamond-based material and having at least one structure 604 coupled to a top surface of the base layer 602 which is configured to provide heat dissipation. Similar to the integrated circuit package 400 of FIG. 4, at least one support structure 610 is fabricated separately from the base layer 602 of the lid, but nevertheless couples the base layer 602 of the lid to the base substrate 612 at a periphery of the bottom and top surfaces respectively. In an embodiment, the support structure 610 may be considered a stiffener ring (frame) that is comprised of a copper-based material, stainless steel-based material, etc. The support structure 610 couples indirectly to the base substrate 612 on one side and the base layer 602 of the lid on the other side via an adhesive 608. The support structure 610 frames, or surrounds, the integrated circuit 614.

In the present embodiment shown, a TIM 616 is situated between the integrated circuit 614 and the base layer 602 of the lid. The TIM 616 is the same as that described above with respect to the integrated circuit package 300 of FIG. 3. Also in the present embodiment shown, the lid includes a top cover 606 that at least partially encloses the at least one heat dissipation structure 604. The top cover 606 is the same as that described above with respect to the integrated circuit package 300 of FIG. 3.

To this end, the embodiments described above with respect to FIGS. 1-6 can enable the direct attachment of the cooling structure to the heat generating die below while allowing the lowest thermal interface resistance via the use of the diamond-based material. The embodiments also allow a minimal form factor cooling solution which enables very high-density system packaging. The embodiments allow a multi-die packaging cooling solution within the package. The embodiments allows multiple independent cooling loops to provide for a targeted cooling solution. The embodiments allow a cooling solution for very large dies by having multiple smaller modular cooling structures to circumvent die curvature and thermal stress related issues. The embodiments reduce the lid coefficient of thermal expansion which can help in reducing stresses on TIMs and therefore enhance reliability. The thermal dissipation provided via the lid structure described herein directly translates into higher power capability for chips and therefor higher performance of chip-based devices such as graphics processing units (GPUs), central processing units (CPUs) and networking products.

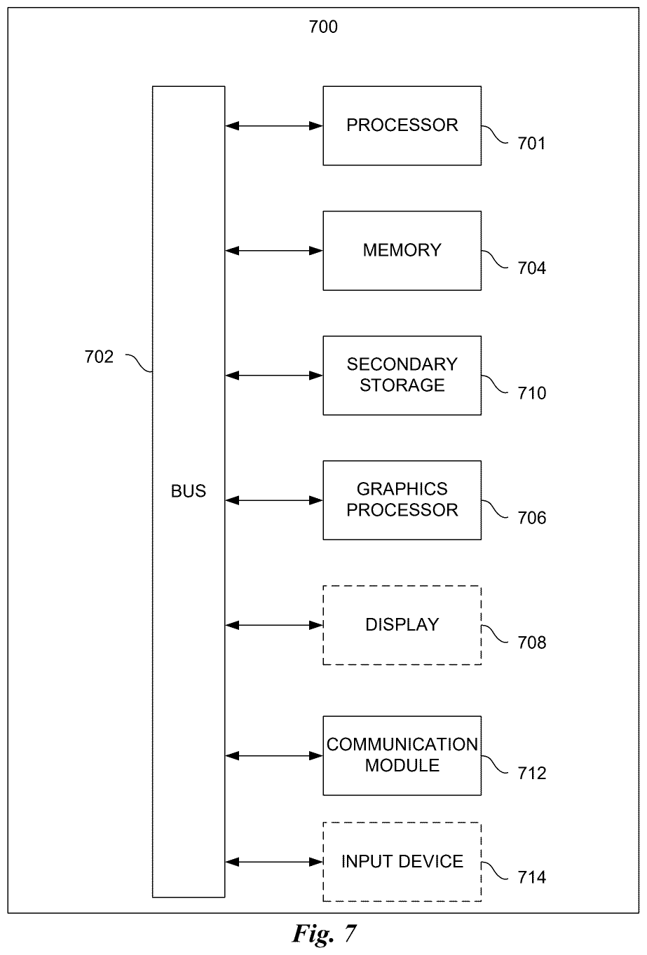

FIG. 7 illustrates an exemplary computing system 700, in accordance with an embodiment. The computing system 700 may be configured to include one or more of the integrated circuit packages described above with respect to FIGS. 1-6.

As shown, the system 700 includes at least one central processor 701 which is connected to a communication bus 702. The system 700 also includes main memory 704 [e.g. random access memory (RAM), etc.]. The system 700 also includes a graphics processor 706 and optionally a display 708.

The system 700 may also include a secondary storage 710. The secondary storage 710 includes, for example, a hard disk drive and/or a removable storage drive, representing a flash drive or other flash storage, etc. The removable storage drive reads from and/or writes to a removable storage unit in a well-known manner.

Computer programs, or computer control logic algorithms, may be stored in the main memory 704, the secondary storage 710, and/or any other memory, for that matter. Such computer programs, when executed, enable the system 700 to perform various functions, including for example any of the methods set forth above. The computer programs, when executed, may also enable such methods. Memory 704, storage 710 and/or any other storage are possible examples of non-transitory computer-readable media.

The system 700 may also include one or more communication modules 712. The communication module 712 may be operable to facilitate communication between the system 700 and one or more networks, and/or with one or more devices (e.g. game consoles, personal computers, servers etc.) through a variety of possible standard or proprietary wired or wireless communication protocols (e.g. via Bluetooth, Near Field Communication (NFC), Cellular communication, etc.).

As also shown, the system 700 may include, in one optional embodiment, one or more input devices 714. The input devices 714 may be a wired or wireless input device. In various embodiments, each input device 714 may include a keyboard, touch pad, touch screen, game controller, remote controller, or any other device capable of being used by a user to provide input to the system 700.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A lid for an integrated circuit package, comprising:
a base layer comprised of a diamond-based material; and
at least one structure coupled to a top surface of the base layer, wherein the at least one structure is configured for providing heat dissipation.

2. The lid of claim 1, wherein the diamond-based material is a diamond sheet.

3. The lid of claim 1, wherein the diamond-based material is a diamond-based composite material.

4. The lid of claim 3, wherein the diamond-based composite material is a silver-diamond composite material.

5. The lid of claim 3, wherein the diamond-based composite material is a copper-diamond composite material.

6. The lid of claim 1, wherein the diamond-based material has a thermal conductivity greater than 400 watts per meter-kelvin.

7. The lid of claim 1, wherein the diamond-based material has a thermal conductivity greater than 800 watts per meter-kelvin.

8. The lid of claim 1, wherein a bottom surface of the base layer of the lid is flat.

9. The lid of claim 1, wherein the at least one structure is at least one channel.

10. The lid of claim 9, wherein the at least one channel is a copper plated channel.

11. The lid of claim 9, wherein the at least one channel is a plurality of uniform channels.

12. The lid of claim 9, wherein the at least one channel is a plurality of non-uniform channels.

13. The lid of claim 1, wherein the at least one structure is a pin array structure.

14. The lid of claim 13, wherein the pin array structure is uniform.

15. The lid of claim 13, wherein the pin array structure is non-uniform.

16. The lid of claim 13, wherein the pin array structure is coupled to the top surface of the base layer of the lid via a film deposited on the top surface of the base layer of the lid.

17. The lid of claim 16, wherein the film is one of:
a nickel-gold composite material, or
a nickel-silver composite material.

18. The lid of claim 1, further comprising:
a top cover at least partially enclosing the at least one structure.

19. The lid of claim 18, wherein the top cover is comprised of a copper-based material.

20. The lid of claim 18, wherein the top cover is comprised of an aluminum-based material.

21. The lid of claim 18, wherein the top cover is comprised of a plastic-based material.

22. The lid of claim 18, wherein the top cover includes at least one opening configured as at least one of an inlet or an outlet to the at least one structure.

23. The lid of claim 1, further comprising:
support structures coupled to the base layer of the lid, wherein the support structures are configured to couple the lid to a base substrate of the integrated circuit package.

24. The lid of claim 23, wherein the support structures and the base layer of the lid are fabricated together.

25. The lid of claim 23, wherein the support structures are coupled to the base layer of the lid via a polymer-based adhesive.

26. An integrated circuit package, comprising:
a base substrate; and
a lid that couples to the base substrate and that includes a base layer comprised of a diamond-based material.

27. The integrated circuit package of claim 26, wherein the base substrate is configured to have at least one die coupled thereto.

28. The integrated circuit package of claim 26, wherein the diamond-based material is a diamond sheet.

29. The integrated circuit package of claim 26, wherein the diamond-based material is a diamond-based composite material.

30. The integrated circuit package of claim 29, wherein the diamond-based composite material is a silver-diamond composite material.

31. The integrated circuit package of claim 29, wherein the diamond-based composite material is a copper-diamond composite material.
